(19) United States
(12) Patent Application Publication
(10) Pub. No.: US 2024/0162688 A1
(43) Pub. Date: May 16, 2024

(54) MIXED ARRAY OF VCSEL DEVICES HAVING DIFFERENT JUNCTION TYPES AND METHODS OF FORMING THE SAME

(71) Applicant: META PLATFORMS TECHNOLOGIES, LLC, Menlo Park, CA (US)

(72) Inventors: Rama Krishna KAMBHAMPATI, Milpitas, CA (US); Jonatan GINZBURG, San Jose, CA (US)

(21) Appl. No.: 17/510,144

(22) Filed: Oct. 25, 2021

Related U.S. Application Data
(60) Provisional application No. 63/234,116, filed on Aug. 17, 2021.

(51) Int. Cl. H01S 5/42; H01S 5/183; H01S 5/34

(52) U.S. Cl. CPC H01S 5/426; H01S 5/18361; H01S 5/3421

(57) ABSTRACT

Various embodiments set forth a light-emitting device that includes: a single die formed from a portion of a semiconductor substrate; a first vertical cavity surface-emitting laser (VCSEL) that is formed from a first set of material layers disposed on the single die; and a second VCSEL that is formed from a second set of material layers disposed on the first set of material layers, wherein the first set of material layers are disposed between the portion of the semiconductor substrate and the second set of material layers.

### CROSS-REFERENCE TO RELATED APPLICATIONS

This application claims priority benefit of the United States Provisional Patent Application titled, “METHOD FOR FORMING SINGLE AND MULTI-JUNCTION VCSEL ARRAYS,” filed on Aug. 17, 2021 and having Ser. No. 63/234,116. The subject matter of this related application is hereby incorporated herein by reference.

### BACKGROUND

### Field of the Various Embodiments

Embodiments of this disclosure relate generally to semiconductor devices and, more specifically, to a mixed array of VCSEL devices having different junction types and methods of forming the same.

### Description of the Related Art

A semiconductor laser is a device that, like a light-emitting diode, can convert electrical energy into light. Through the process of stimulated emission, a semiconductor laser generates light with the same phase, coherence, and wavelength. Because semiconductor lasers are a reliable, efficient, and inexpensive device for generating such light, there are many commercial, industrial, and scientific applications for semiconductor lasers. Examples of such applications include telecommunications, compact disk and laser disk players, high-speed printers, and augmented reality (AR) and virtual reality (VR) systems.

Semiconductor lasers include edge-emitting lasers, which output radiation parallel to the plane of the semiconductor substrate from which the laser is formed, and surface-emitting lasers (SELs), which output radiation perpendicular to such a plane. For AR and VR devices in particular, the vertical-cavity surface-emitting laser (VCSEL) is commonly employed as a light source. In a VCSEL, the “vertical” direction indicates a direction perpendicular to the plane of the semiconductor substrate on which the constituent layers are epitaxially grown or deposited, where “up” refers to the direction that such layers are grown or deposited and down refers to the direction toward the semiconductor substrate. VCSELs have many advantages over edge-emitting lasers, such as low threshold current, single longitudinal mode, a circular output beam profile, ease of fiber coupling, and scalability to monolithic laser arrays. For example, a large number of VCSELs (e.g., hundreds or thousands) can be fabricated on a single semiconductor die.

One disadvantage of VCSELs is that, even though a large number of individual VCSEL emitters can be formed on a single semiconductor die, all such VCSELs are limited to the same configuration. Specifically, the VCSELs formed on a single die are configured with the same junction type, for example, single junction, two junction, three junction, etc. This is because the junction region (or regions) of a semiconductor laser is formed by depositing various layers of p-doped, n-doped, and insulating layers on essentially the entire surface of a semiconductor substrate, and the number of junctions included in the semiconductor lasers fabricated from the substrate is defined by the structure of such layers. Therefore, for applications in which laser light sources are needed with both the higher power and higher efficiency of a multi-junction VCSEL and the lower power of a single-junction VCSEL, multiple laser die must be employed. However, using more die in a laser source increases the size and complexity of the laser source, which is highly undesirable.

As the foregoing illustrates, what is needed in the art are more effective techniques for fabricating VCSEL devices.

### SUMMARY

One embodiment of the present disclosure sets forth a light-emitting device that includes: a single die formed from a portion of a semiconductor substrate; a first vertical cavity surface-emitting laser (VCSEL) that is formed from a first set of material layers disposed on the single die; and a second VCSEL that is formed from a second set of material layers disposed on the first set of material layers, wherein the first set of material layers are disposed between the portion of the semiconductor substrate and the second set of material layers.

One advantage of the techniques disclosed herein is that multiple types of VCSELs can be formed on a single die. As a result, a mixed array of VCSELs that have different junction types can be implemented in a laser-based design with a single semiconductor die. This technical advantage represents one or more technological advancements over prior art approaches.

### BRIEF DESCRIPTION OF THE DRAWINGS

So that the manner in which the above recited features of the various embodiments can be understood in detail, a more particular description of the disclosed concepts, briefly summarized above, may be had by reference to various embodiments, some of which are illustrated in the appended drawings. It is to be noted, however, that the appended drawings illustrate only typical embodiments of the disclosed concepts and are therefore not to be considered limiting of scope in any way, and that there are other equally effective embodiments.

FIG. 1 is a perspective view of a light-emitting device, according to various embodiments.

FIG. 2 is a cross-sectional view of the light-emitting device of FIG. 1 taken at section A-A in FIG. 1, according to various embodiments.

FIG. 3 sets forth a flowchart of method steps for fabricating a light-emitting device, according to various embodiments.

FIGS. 4A-4K schematically illustrate various steps of the fabrication process, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it is apparent to one of skilled in the art that the disclosed concepts may be practiced without one or more of these specific details.

### Configuration Overview

Embodiments described herein may include or be implemented in conjunction with an artificial reality system. Artificial reality is a form of reality that has been adjusted in some manner before presentation to a user, which may include, for example, a virtual reality (VR) system, an augmented reality (AR) system, a mixed reality (MR) system, a hybrid reality system, or some combination and/or derivatives thereof. Artificial reality content may include, without limitation, completely generated content or generated content combined with captured (e.g., real-world) content. The artificial reality content may include, without limitation, video, audio, haptic feedback, or some combination thereof. The artificial reality content may be presented in a single channel or in multiple channels (such as stereo video that produces a three-dimensional effect to the viewer). Additionally, in some embodiments, artificial reality systems may also be associated with applications, products, accessories, services, or some combination thereof, that are used to, e.g., create content in an artificial reality system and/or are otherwise used in (e.g., perform activities in) an artificial reality system. The artificial reality system may be implemented on various platforms, including a head-mounted display (HMD) connected to a host computer system, a standalone HMD, a mobile device or computing system, or any other hardware platform capable of providing artificial reality content to one or more viewers.

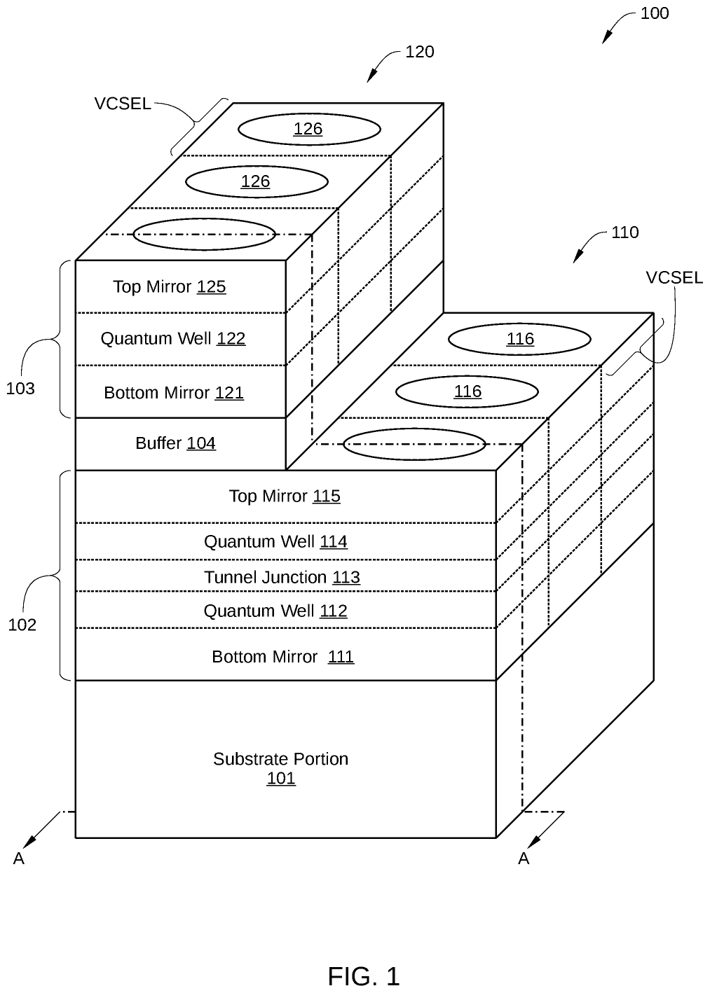

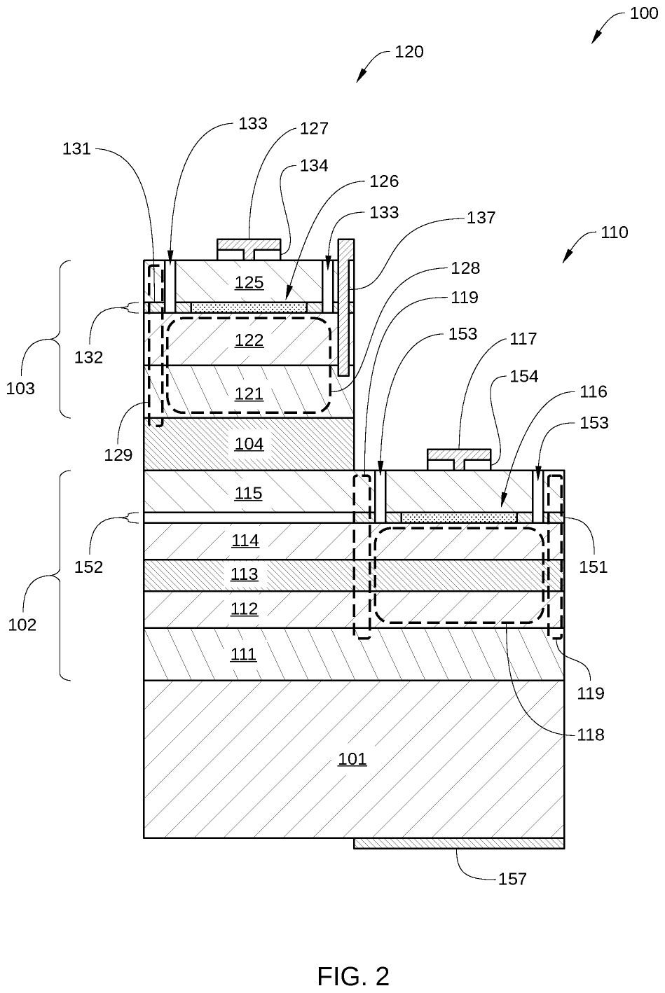

FIG. 1 is a perspective view of a light-emitting device 100, according to various embodiments, and FIG. 2 is a cross-sectional view of light-emitting device 100 taken at section A-A in FIG. 1, according to various embodiments. In the embodiment illustrated in FIGS. 1 and 2, light-emitting device 100 includes a first array 110 of VCSELs and a second array 120 of VCSELs formed on a substrate portion 101. Substrate portion 101 is diced or otherwise separated from a semiconductor substrate after formation of first array 110 and second array 120. Thus, light-emitting device 100 is configured as a single semiconductor die.

First array 110 includes three VCSELs configured as a linear array and second array 120 includes three VCSELs configured as a linear array. In other embodiments, first array 110 and/or second array 120 includes more than three or fewer than three VCSELs. For example, in some embodiments, first array 110 and second array 120 each include hundreds or thousands of individual VCSELs. In some embodiments, each VCSEL in first array 110 is electrically coupled together by at least one metal trace included in light-emitting device 100, such as top metallization 117. Thus, in such embodiments, each VCSEL in first array 110 can be controlled together simultaneously with a single input signal via the metal trace. Similarly, in some embodiments, each VCSEL in second array 120 is electrically coupled together by at least one metal trace included in light-emitting device 100, such as top metallization 127. Thus, in such embodiments, each VCSEL in second array 110 can be controlled together simultaneously with a single input signal via the metal trace. For clarity, top metallization 117 and 127 are omitted from FIG. 1 and only shown in FIG. 2.

In the embodiment illustrated in FIGS. 1 and 2, the three VCSELs of first array 110 are configured as multi-junction VCSELs. As such, the three VCSELs of first array 110 are formed from a first set of material layers 102 that are disposed on substrate portion 101 and include a bottom mirror layer 111, a top mirror layer 115, multiple quantum well layers 112 and 114, and a tunnel junction layer 113 that is disposed between quantum well layers 112 and 114. Bottom mirror layer 111 and top mirror layer 115 are configured to reflect light generated in an active region of each VCSEL of first array 110, and are oriented substantially parallel to the plane of substrate portion 101. In some embodiments, bottom mirror layer 111 and top mirror layer 115 are configured as distributed Bragg reflectors, and include a plurality of material layers (not shown) with alternating high and low refractive indices. In such embodiments, when material layers included in bottom mirror layer 111 or top mirror layer 115 has a thickness of a quarter of the laser wavelength, very high intensity reflectivities on the order of 99% or above can be realized. Quantum well layers 112 and 114 form an active region of each VCSEL of first array 110. Thus, a portion of quantum well layers 112 and 114 and tunnel junction layer 113 are disposed in a laser cavity (or optical cavity) 118 (dashed lines) of each VCSEL of first array 110. Laser cavity 118 for each VCSEL is typically bounded by bottom mirror layer 111, top mirror layer 115, and resistive isolation regions 119.

As shown in FIG. 2, top mirror layer 115 includes an aperture 116 through which light is emitted from each VCSEL of first array 110. In the embodiment illustrated in FIG. 2, aperture 116 is an oxide aperture that is formed or defined by one or more oxidized portions 151 (cross-hatched) of an oxidizing layer 152 that is included in top mirror layer 115. That is, aperture 116 corresponds to the portions of oxidizing layer 152 that are not oxidized. In such embodiments, oxidizing layer 152 may be exposed to an oxidation process via one or more oxidation trenches 153 that are formed in first set of material layers 102 prior to the oxidation process. In other embodiments, aperture 116 can be formed by other conventional techniques, such as techniques that lower the reflectivity of the exit mirror (in this case top mirror layer 115) relative to the opposing mirror (in this case bottom mirror layer 111).

To enable operation of the VCSELs of first array 110, each VCSEL of first array 110 includes top metallization 117, which is electrically coupled to top mirror layer 115, and a bottom metallization 157, which is electrically coupled to substrate portion 101. Further, in the embodiment illustrated in FIG. 2, top metallization 117 is shown formed on ohmic contact 154. In such embodiments, ohmic contact 154 is configured to enable a suitable metal-semiconductor ohmic contact to be formed between top metallization 117 and a semiconductor layer of first set of material layers 102, such as top mirror layer 115.

The three VCSELs of second array 120 have a similar general configuration to that of the VCSELs of first array 120, except that the VCSELs of second array 120 have a different number of junctions than the VCSELs of first array 110. In the embodiment illustrated in FIGS. 1 and 2, the three VCSELs of second array 120 are configured as single-junction VCSELs. As such, the three VCSELs of second array 120 are formed from a second set of material layers 103 that are formed after first set of material layers 102, and include a bottom mirror layer 121, a top mirror layer 125, and a single quantum well layer 122. Thus, second set of material layers 103 are disposed on first set of material layers 102 or a buffer layer 104. In other embodiments, the VCSELs of second array 120 may include more than two quantum well layers, and therefore include more junctions than the VCSELs of first array 110.

Bottom mirror layer 121 and top mirror layer 125 are similar in configuration to bottom mirror layer 111 and top mirror layer 115; quantum well layer 122 is similar in configuration to quantum well layer 112, and apertures 126 are similar in configuration to apertures 116. Thus, quantum well layer 122 forms the active region of each VCSEL of second array 120, and a portion of quantum well layer 122 is disposed in a laser cavity (or optical cavity) 128 (dashed lines) of each VCSEL of second array 120. Further, laser cavity 128 for each VCSEL is typically bounded by bottom mirror layer 121, top mirror layer 125, and resistive isolation regions 129. In some embodiments, aperture 126 is an oxide aperture that is formed or defined by one or more oxidized portions 131 (cross-hatched) of an oxidizing layer 132 that is included in top mirror layer 125. That is, aperture 126 corresponds to the portions of oxidizing layer 132 that are not oxidized. In other embodiments, aperture 126 can be formed by other conventional techniques, such as techniques that lower the reflectivity of the exit mirror (in this case top mirror layer 125) relative to the opposing mirror (in this case bottom mirror layer 121).

To enable operation of the VCSELs of second array 120, each VCSEL of second array 120 includes top metallization 127, which is electrically coupled to top mirror layer 125, and a bottom contact 137, which is electrically coupled to bottom mirror layer 121 by a metallized via. Further, in the embodiment illustrated in FIG. 2, top metallization 127 is shown formed on an ohmic contact 134. In such embodiments, ohmic contact 134 is configured to enable a suitable metal-semiconductor ohmic contact to be formed between top metallization 127 and a semiconductor layer of second set of material layers 103, such as top mirror layer 125.

In some embodiments, first set of material layers 102 is separated by second set of material layers 103 by buffer layer 104. In such embodiments, buffer layer 104 electrically isolates VCSELs of first array 110 from VCSELs of second array 120. In such embodiments, buffer layer 104 may include an undoped semiconductor material, such as an epitaxially grown silicon-based semiconductor material. In some embodiments, the undoped semiconductor material has a thickness on the order of about 0.5 to 5 microns. Alternatively or additionally, in some embodiments, buffer layer 104 includes an electrically insulating material.

In an example embodiment, top mirror layer 115 and top mirror layer 125 each have a thickness on the order of about 2-3 microns and include a plurality (e.g., 30 pairs) of alternating layers of gallium-arsenide (GaAs) and p-doped aluminum-gallium-arsenide (AlGaAs). In the example embodiment, quantum well layer 112, quantum well layer 114, and quantum well layer 122 each include a layer of indium-gallium-arsenide (InGaAs) having a thickness on the order of about 10-100 nanometers. In the example embodiment, buffer layer 104 includes a 1 micron layer of undoped silicon, while ohmic contact 134 and ohmic contact 154 each include a highly p-doped GaAs contact layer. In the example, substrate portion 101 includes a portion of a GaAs wafer, and bottom mirror layer 111 and bottom mirror layer 121 each have a thickness on the order of about 2-3 microns and include a plurality (e.g., 15 pairs) of alternating layers of GaAs and n-doped aluminum-arsenide (AlAs). In the example embodiment described above, material layers on the bottom side (e.g., the side closest to substrate portion 101) of an active region are described being doped to have a first conductivity type (e, n-type), and material layers on the top side (e, the side farthest from substrate portion 101) of the active region are described being doped to have a second conductivity type (e.g., p-type). In other embodiments, an opposing doping scheme may be employed. Alternatively or additionally, one or more layers included in first set of material layers 102 and/or second set of material layers 103 may be undoped, and/or more heavily doped than in the exemplary description above.

### Fabrication Process for an Array of VCSELs with Different Junction Types

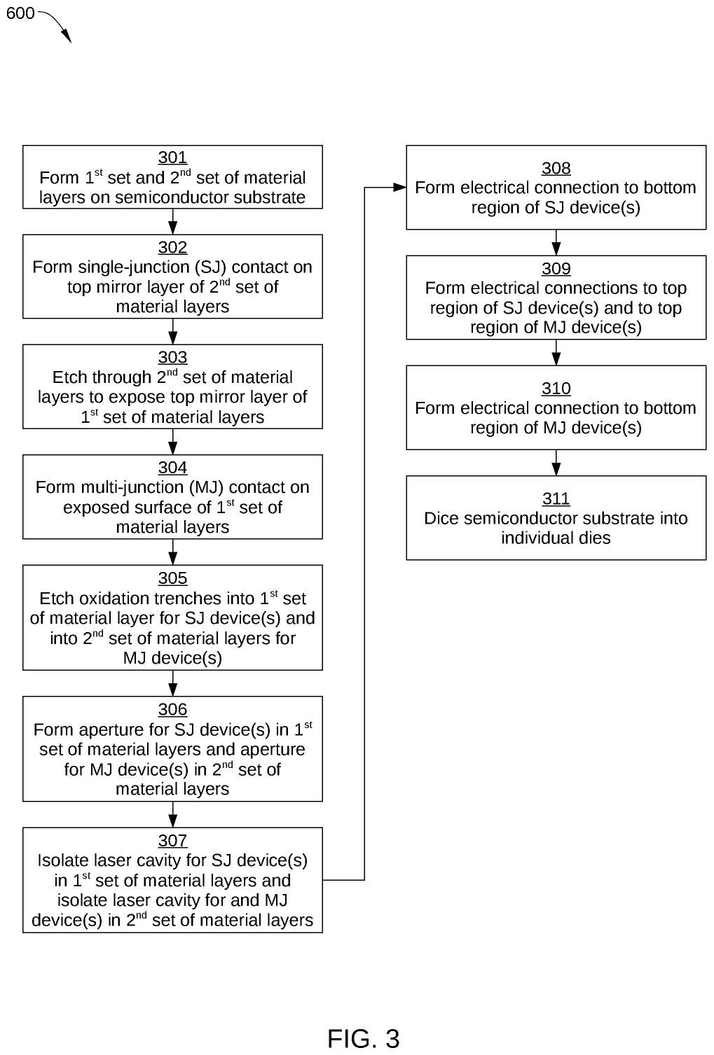

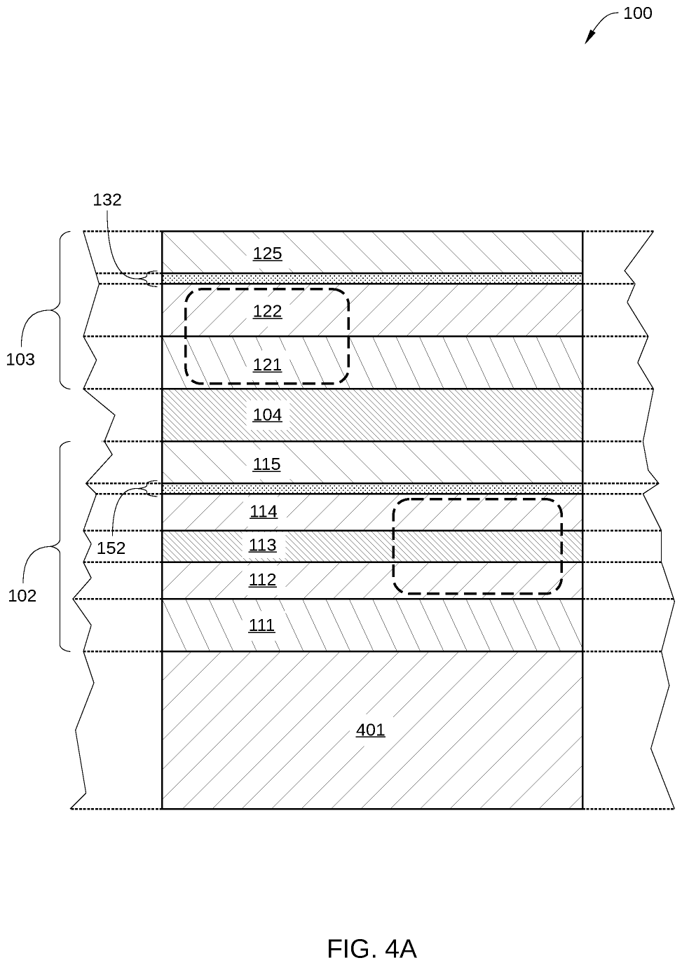

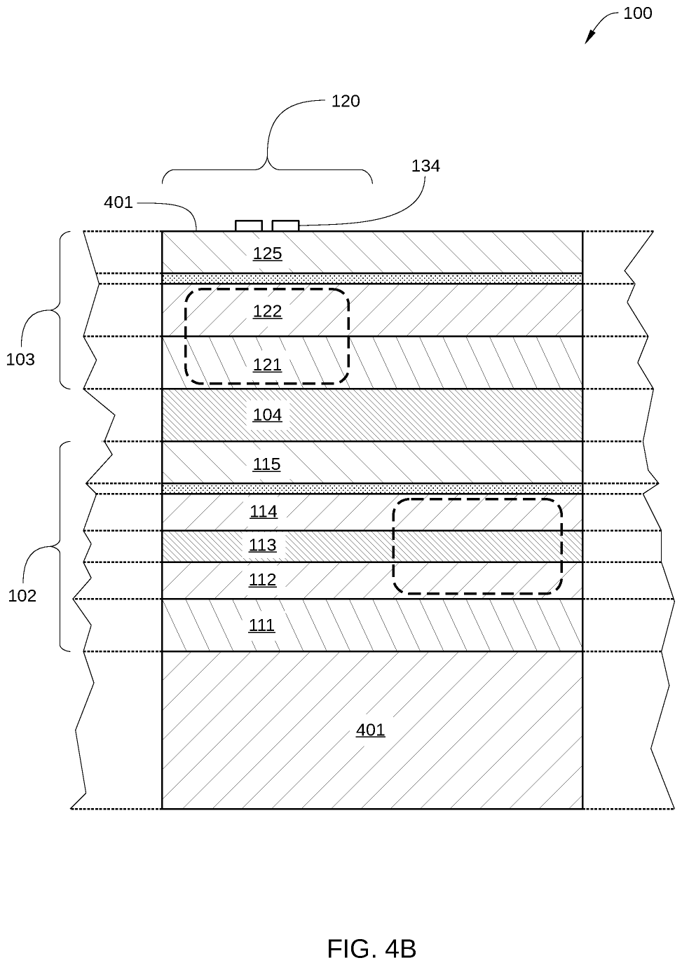

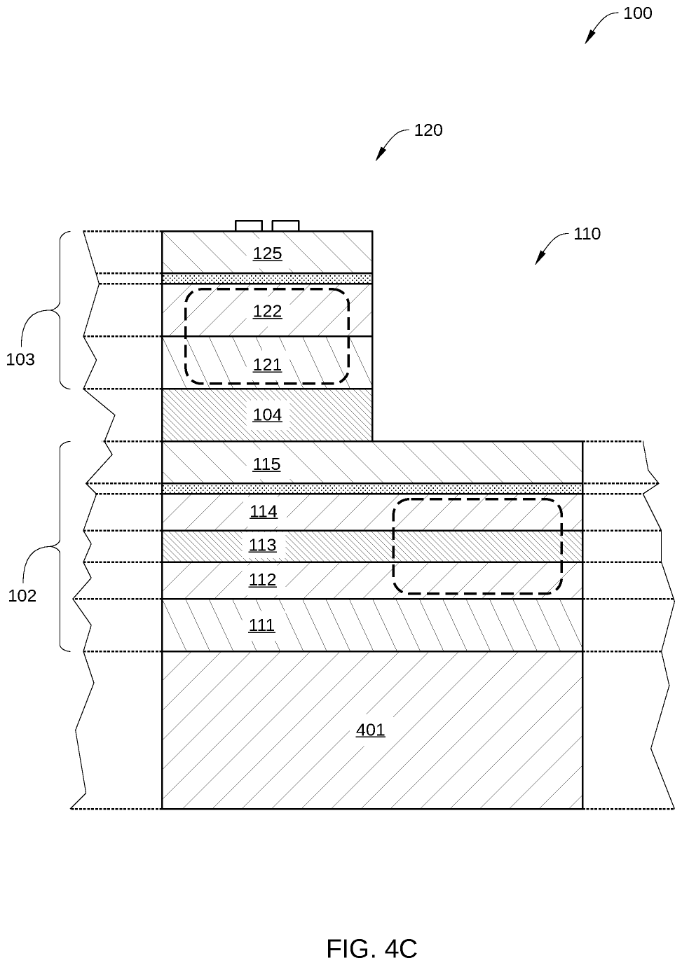

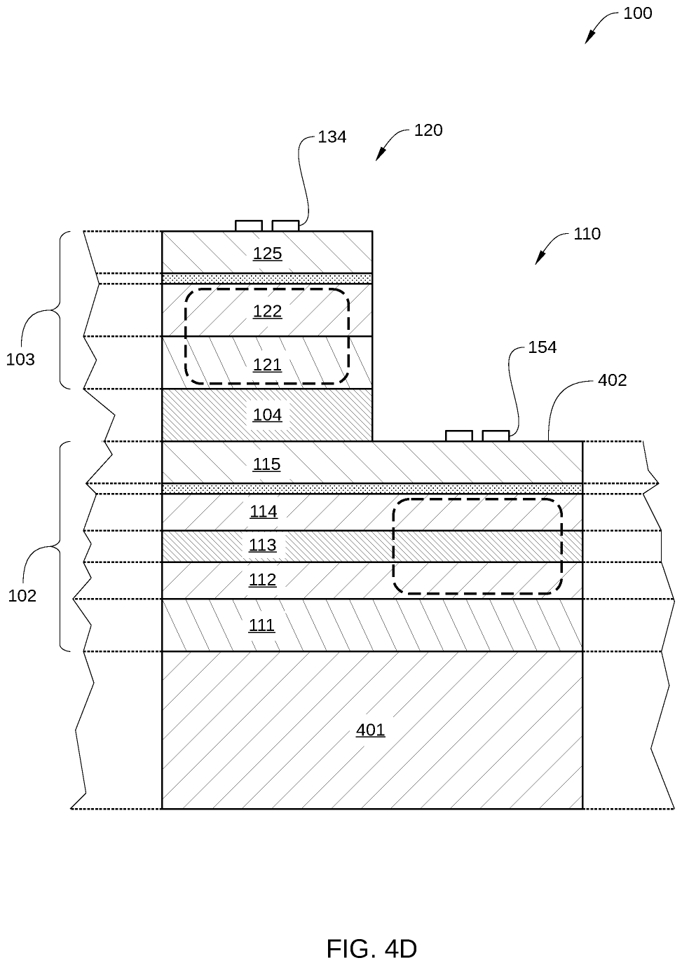

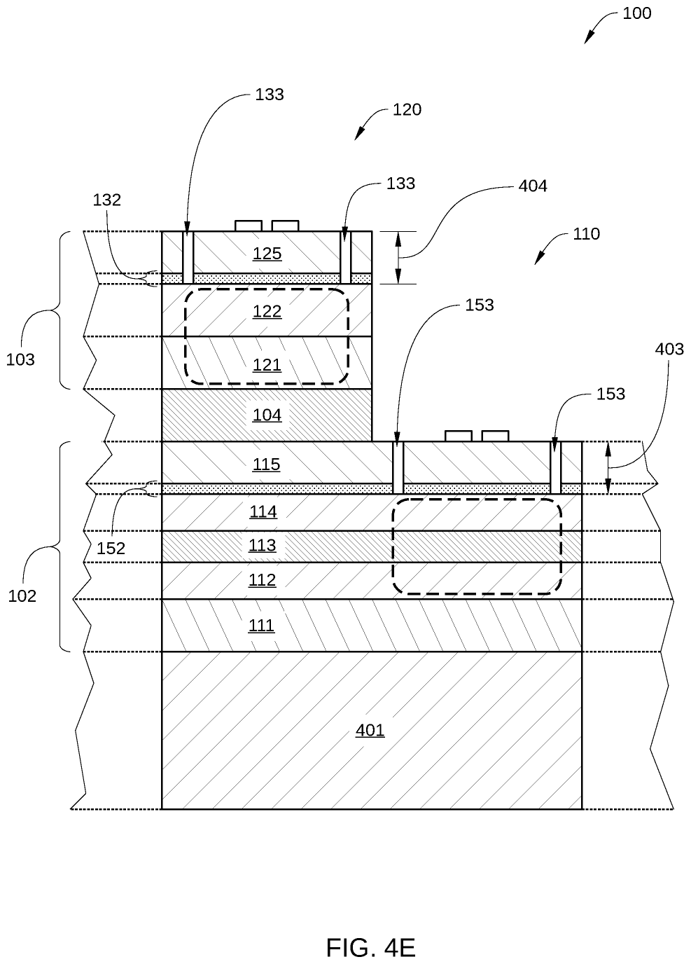

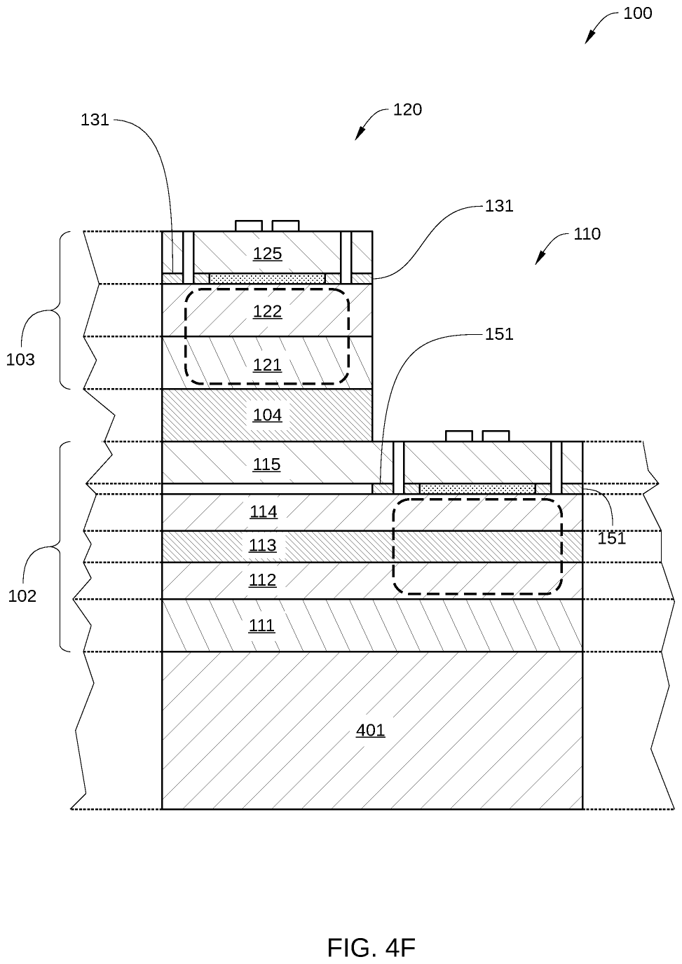

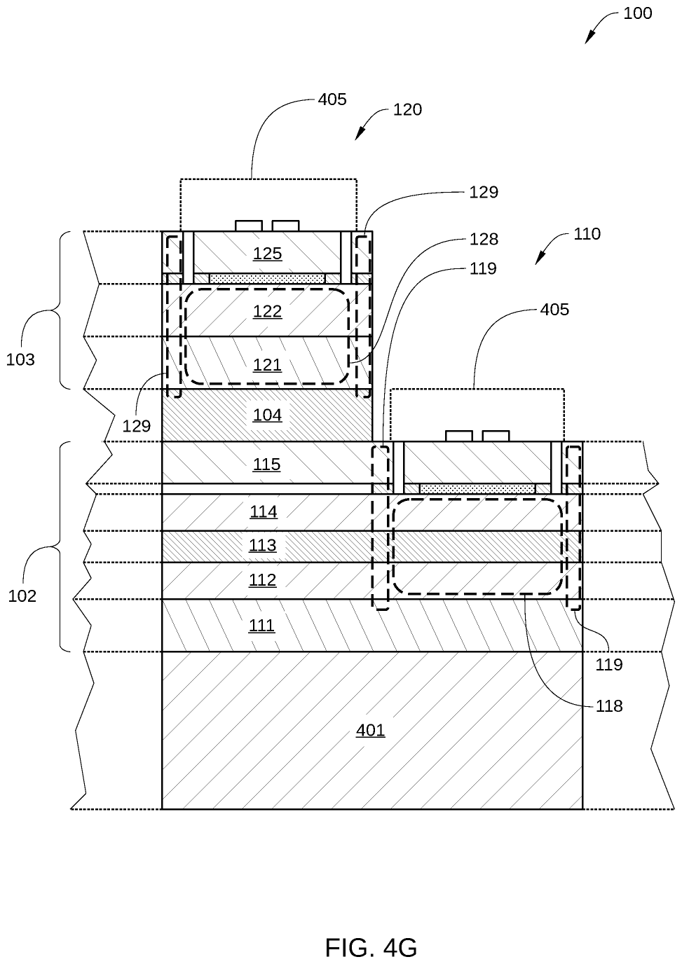

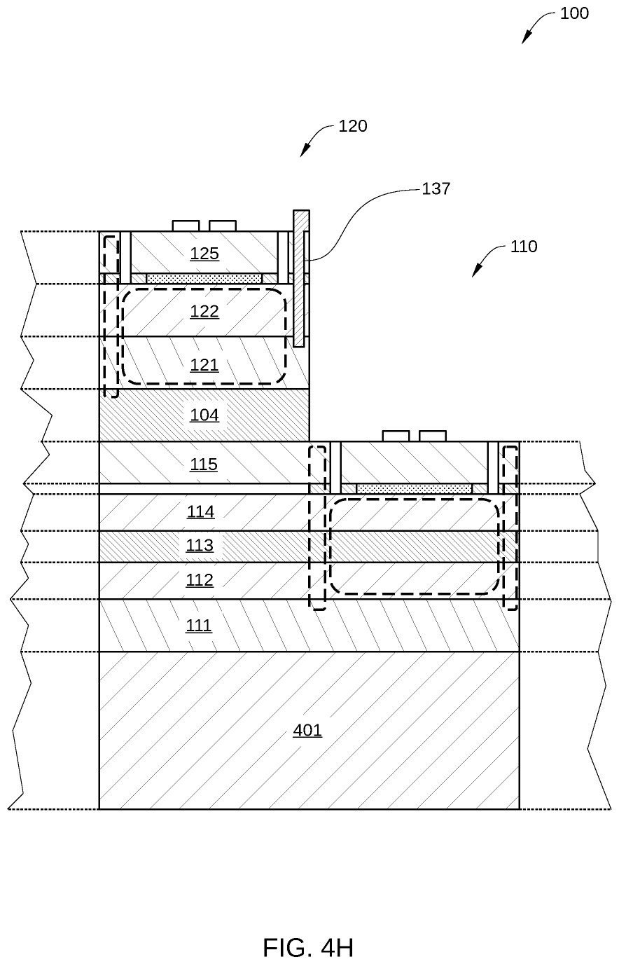

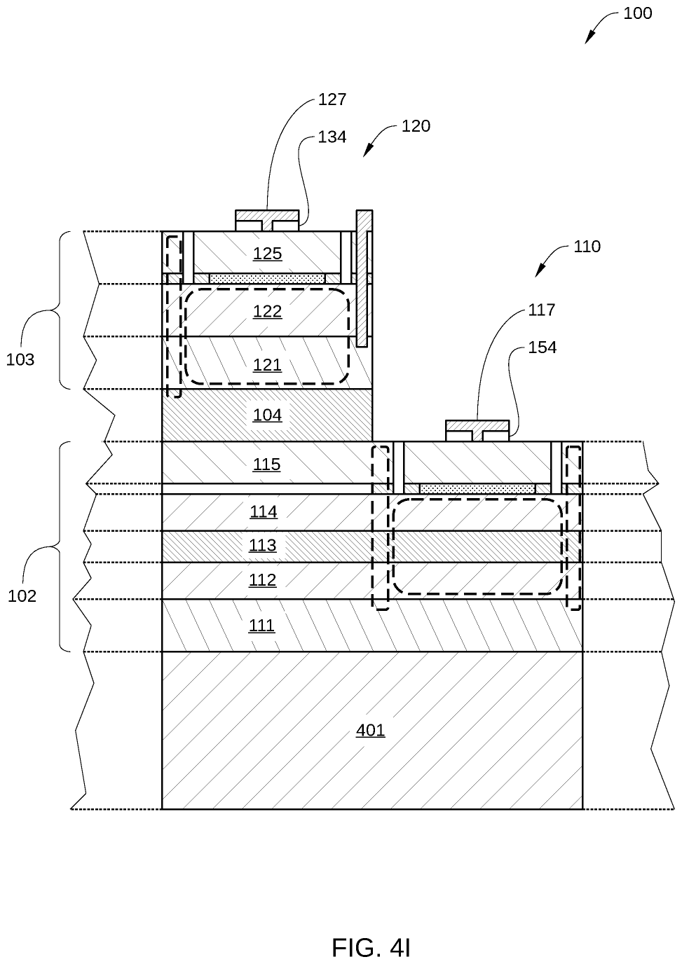

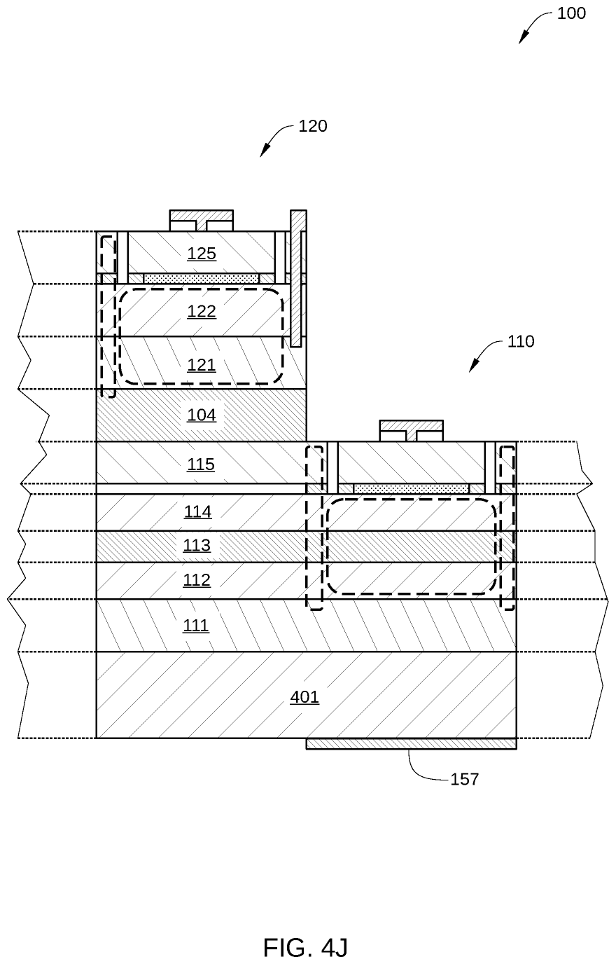

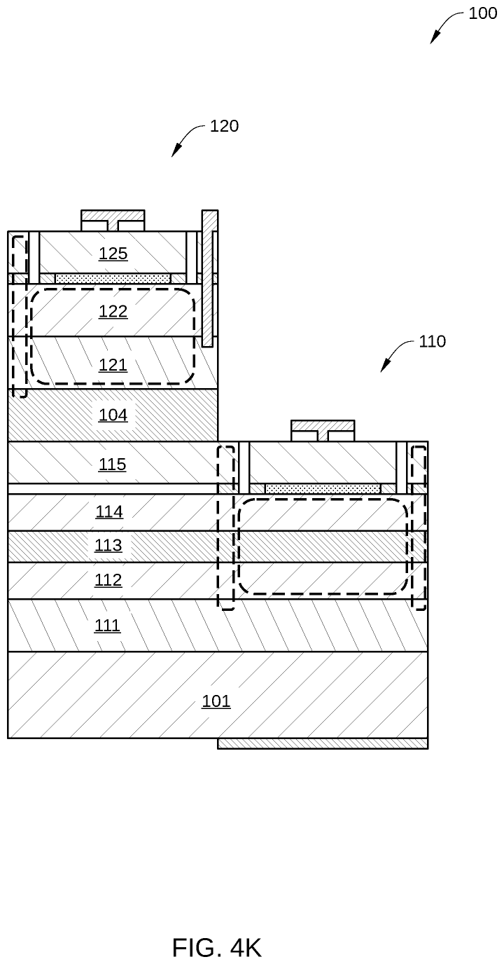

FIG. 3 sets forth a flowchart of method steps for fabricating a light-emitting device, according to various embodiments. Although the method steps of a fabrication process 300 are described in conjunction with the system of FIGS. 1 and 2, persons skilled in the art will understand that any system configured with a mixed array of VCSELs having different junction types is within the scope of the embodiments. FIGS. 4A-4K schematically illustrate various steps of fabrication process 300, according to various embodiments. In the embodiment illustrated in FIGS. 3 and 4A-4K, VCSELs associated with first set of material layers 102 are described as multi-junction (MJ) devices and VCSELs associated with second set of material layers 102 are described as single-junction (SJ) devices. In other embodiments, VCSELs associated with first set of material layers 102 may be configured as SJ devices or devices having any junction type that is different (e.g., having a different number of junctions) than VCSELs associated with second set of material layers 103. Similarly, in other embodiments, VCSELs associated with second set of material layers 103 may be configured as MJ devices or devices having any junction type that is different than VCSELs associated with first set of material layers 103.

As shown, fabrication process 300 begins at step 301, where first set of material layers 102, buffer layer 104, and second set of material layers 103 are formed on a semiconductor substrate 401, as shown in FIG. 4A. In some embodiments, semiconductor substrate 401 is a GaAs wafer or other suitable semiconductor wafer that can subsequently be diced into individual dice, such as substrate portion 101 in FIGS. 1 and 2. In some embodiments, one or more of the layers included in first set of material layers 102, second set of material layers 103, and/or buffer layer 104 is formed via epitaxial growth on semiconductor substrate 401. Alternatively, in some embodiments, one or more layers formed on semiconductor substrate 401 are formed via any other technical feasible approach suitable for fabricating a light-emitting device. As shown, buffer layer 104 is formed on first set of material layers 102, and second set of material layers 103 is subsequently formed on buffer layer 104. Further, in some embodiments, top mirror layer 115 includes oxidizing layer 152 and top mirror layer 125 includes oxidizing layer 132.

In step 302, ohmic contact 134 is formed on a top region of second set of material layers 103, such as an exposed surface 401 of top mirror layer 125, as shown in FIG. 4B. Thus, ohmic contact 134 is formed for the SJ devices associated with second set of material layers 103. As described above, ohmic contact 134 is an electrical connection that includes a suitable metal-semiconductor ohmic contact for enabling a metal trace, such as top metallization 127, to be electrically coupled to VCSELs of second array 120. In some embodiments, ohmic contact includes a thin metal-containing layer that is selected based on the composition of the top region of second set of material layers 103. In some embodiments, an anneal process is performed on the thin metal layer in step 302 to produce a targeted semiconductor-metal bond.

In step 303, a portion of second set of material layers 103 is etched to expose top mirror layer 115 included in first set of material layers, as shown in FIG. 4C. Any technically feasible masking and etching technique can be employed in step 303 to remove the portion of second set of material layers 103, including reactive ion etching (RIE).

In step 304, ohmic contact 154 is formed on a top region of first set of material layers 102, such as an exposed surface 402 of top mirror layer 115, as shown in FIG. 4D. Thus, ohmic contact 154 is formed for the MJ devices associated with first set of material layers 102. In some embodiments, similar techniques employed to form ohmic contact 134 in step 302 are employed in step 304.

In step 305, oxidation trenches 153 are formed in first set of material layers 102 and oxidation trenches 133 are formed in second set of material layers 103, as shown in FIG. 4E. A depth 403 of oxidation trenches 153 is selected so that at least a portion of oxidizing layer 152 is exposed and a depth 404 of oxidation trenches 133 is selected so that at least a portion of oxidizing layer 132 is exposed. In some embodiments, oxidation trenches 133 and oxidation trenches 153 are formed in a single etch process that is performed on the first set of material layers and the second set of material layers simultaneously.

In step 306, apertures 116 are formed in first set of material layers 102 and apertures 126 are formed in second set of material layers 103, as shown in FIG. 4F. Thus, apertures are formed for the MJ devices and the SJ devices associated with light-emitting device 100. In embodiments in which apertures 116 and/or apertures 126 are oxide apertures, step 306 includes an oxidation process in which oxidized portions 131 and/or oxidized portions 151 are formed.

In step 307, laser cavities 118 in first set of material layers 102 and laser cavities 128 in second set of material layers 103 are isolated, as shown in FIG. 4G. Specifically, in the embodiment illustrated in FIG. 4G, a single ion implantation process is performed simultaneously on unmasked regions of first set of material layers 102 and second set of material layers 103. In such embodiments, a crystal lattice (not shown) of a portion of at least one semiconductor layer included in the first set of material layers (e.g., top mirror layer 115) is damaged by the ion implantation process. As a result, electrical resistivity is increased in the portion of the at least one semiconductor layer, and resistive isolation regions 119 proximate laser cavities 118 are formed. Thus, each laser cavity 118 included in first array 110 is an isolated laser cavity from which current is resistively isolated from adjacent laser cavities 118. Similarly, in such embodiments, a crystal lattice (not shown) of a portion of at least one semiconductor layer included in the second set of material layers (e.g., top mirror layer 125) is also damaged by the ion implantation process. As a result, electrical resistivity is increased in the portion of the at least one semiconductor layer, and resistive isolation regions 129 proximate laser cavities 128 are formed. Thus, each laser cavity 128 included in first array 120 is an isolated laser cavity from which current is resistively isolated from adjacent laser cavities 128.

For reference, ion implant masks 405 (dashed lines) are also shown in FIG. 4G, and indicate regions of first set of material layers 102 and second set of material layers 103 that are not altered in step 307.

In step 308, first electrical connections (e.g., bottom contacts 137) are formed that connect bottom mirror layer 121 to a top metallization, as shown in FIG. 4H. In some embodiments, the first electrical connections are formed in multiple process steps (e.g., via etching and via fill) prior to the formation of second electrical connections and third electrical connections (described below). Alternatively, in some embodiments, step 308 is performed after step 309, and the first electrical connections are formed after the second electrical connections and the third electrical connections.

In step 309, electrical connections are formed on a top region of second set of material layers 103 and on a top region of first set of material layers 102, as shown in FIG. 4I. In the embodiment illustrated in FIG. 4I, second electrical connections are formed (e.g., top metallization 127) that contact ohmic contact 134, and third electrical connections are formed (e.g., top metallization 117) that contact ohmic contact 154. Thus, in step 309, electrical connections to a top region of the SJ devices of second array 120 and electrical connections to a top region of the MJ devices of first array 110 are formed. In some embodiments, the formation of the second electrical connections and the third electrical connections is performed in a single metal deposition process, such as electroplating, e-beam deposition, or any other technically feasible metal deposition technique. Thus, in such embodiments, the second electrical connections and the third electrical connections are formed simultaneously.

In step 310, a respective electrical connection to a bottom region of each MJ device included first array 110 is formed, such as a bottom contact. For example, in the embodiment illustrated in FIG. 4J, bottom metallization 157 is formed on and electrically coupled to a bottom surface of semiconductor substrate 401 after semiconductor substrate 401 is polished down to a final thickness.

In step 311, substrate portion 101, along with first array 110 and second array 120, is separated from semiconductor substrate 410, as shown in FIG. 4K.

By way of example, in the embodiments described above, first array 110 and second array 120 each include VCSELs configured to emit laser light from a top surface. In other embodiments, the VCSELs included in first array 110 and/or the VCSELs included in second array 120 can be configured to emit laser light from a bottom surface, for example through substrate portion 101.

One advantage of the techniques disclosed herein is that multiple types of VCSELs can be formed on a single die. As a result, VCSELs or arrays of VCSELs that have different numbers of junctions can be implemented in a laser-based design with a single semiconductor die. This technical advantage represents one or more technological advancements over prior art approaches.

1. In some embodiments, a light-emitting device includes: a single die formed from a portion of a semiconductor substrate; a first vertical cavity surface-emitting laser (VCSEL) that is formed from a first set of material layers disposed on the single die; and a second VCSEL that is formed from a second set of material layers disposed on the first set of material layers, wherein the first set of material layers are disposed between the portion of the semiconductor substrate and the second set of material layers.

2. The light-emitting device of clause 1, further comprising a first array of VCSELs that are formed from the first set of material layers and a second array of VCSELs that are formed from the second set of material layers.

3. The light-emitting device of clause 1 or 2, wherein each VCSEL in the first array of VCSELs is electrically coupled to at least one other VCSEL in the first array of VCSELs by at least one metal trace included in the light-emitting device.

4. The light-emitting device of any of clauses 1-3, wherein each VCSEL in the second array of VCSELs is electrically coupled to at least one other VCSEL in the first array of VCSELs by at least one metal trace included in the light-emitting device.

5. The light-emitting device of any of clauses 1-4, wherein the at least one metal trace is electrically coupled to a contact that is disposed on a top mirror of the second VCSEL.

6. The light-emitting device of any of clauses 1-5, wherein each VCSEL in the first array of VCSELs includes a high-resistivity current-confinement region that resistively isolates a laser cavity of the VCSEL from a laser cavity of an adjacent VCSEL in the first array of VCSELs.

7. The light-emitting device of any of clauses 1-6, further comprising a buffer layer disposed between the first set of material layers and the second set of material layers.

8. The light-emitting device of any of clauses 1-7, wherein the buffer layer is disposed between an upper mirror included in the first set of material layers and a lower mirror included in the second set of material layers.

9. The light-emitting device of any of clauses 1-8, wherein the first set of material layers comprises a first set of epitaxially grown layers and the second set of material layers comprises a second set of epitaxially grown layers.

10. The light-emitting device of any of clauses 1-9, wherein the first VCSEL comprises a multi-junction VCSEL and the second VCSEL comprises a single-junction VCSEL.

11. In some embodiments, a method of forming a light-emitting device includes: forming a first set of material layers on a semiconductor substrate and a second set of material layers on the first set of material layers; etching a portion of the second set of material layers to expose a top mirror layer included in the first set of material layers; performing ion implantation on the first set of material layers and the second set of material layers to form a first isolated laser cavity within the first set of material layers and a second isolated laser cavity within the second set of material layers; separating a die portion from the semiconductor substrate, wherein the die portion includes the first isolated laser cavity and the second isolated laser cavity.

12. The method of clause 11, further comprising simultaneously forming a first aperture associated with the first isolated laser cavity and a second aperture associated with the second isolated laser cavity via a single oxidation process.

13. The method of clauses 11 or 12, further comprising, prior to the single oxidation process, forming at least one oxidation trench for forming the first aperture and at least one oxidation trench for forming the second aperture.

14. The method of any of clauses 11-13, wherein forming the at least one oxidation trench for forming the first aperture and the at least one oxidation trench for forming the second aperture comprises performing a single etch process on the first set of material layers and the second set of material layers simultaneously.

15. The method of any of clauses 11-14, further comprising, forming a first electrical connection to a top region of the first set of material layers and a second electrical connection to a top region of the second set of material layers.

16. The method of any of clauses 11-15, wherein the top region of the first set of material layers comprises the top mirror layer and the top region of the second set of material layers comprises a top mirror layer included in the second set of material layers.

17. The method of any of clauses 11-16, wherein forming the first electrical connection and the second electrical connection comprises simultaneously depositing a metal layer on the top region of the first set of material layers and a metal layer on the top region of the second set of material layers in a single metal deposition process.

18. The method of any of clauses 11-17, wherein forming the first set of material layers on the semiconductor substrate comprises epitaxially growing the first set of material layers on the semiconductor substrate.

19. The method of any of clauses 11-18, wherein the first set of material layers includes an undoped buffer layer on which the second set of material layers is formed.

20. The method of any of clauses 11-19, wherein performing the ion implantation on the first set of material layers and the second set of material layers comprises performing a single ion implantation process simultaneously on the first set of material layers and the second set of material layers.

Any and all combinations of any of the claim elements recited in any of the claims and/or any elements described in this application, in any fashion, fall within the contemplated scope of the present disclosure and protection.

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

The descriptions of the various embodiments have been presented for purposes of illustration, but are not intended to be exhaustive or limited to the embodiments disclosed. Many modifications and variations is apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a ““module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It is understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A light-emitting device, comprising:
a single die formed from a portion of a semiconductor substrate;
a first vertical cavity surface-emitting laser (VCSEL) that is formed from a first set of material layers disposed on the single die; and
a second VCSEL that is formed from a second set of material layers disposed on the first set of material layers,
wherein the first set of material layers are disposed between the portion of the semiconductor substrate and the second set of material layers.

2. The light-emitting device of claim 1, further comprising a first array of VCSELs that are formed from the first set of material layers and a second array of VCSELs that are formed from the second set of material layers.

3. The light-emitting device of claim 2, wherein each VCSEL in the first array of VCSELs is electrically coupled to at least one other VCSEL in the first array of VCSELs by at least one metal trace included in the light-emitting device.

4. The light-emitting device of claim 3, wherein each VCSEL in the second array of VCSELs is electrically coupled to at least one other VCSEL in the first array of VCSELs by at least one metal trace included in the light-emitting device.

5. The light-emitting device of claim 3, wherein the at least one metal trace is electrically coupled to a contact that is disposed on a top mirror of the second VCSEL.

6. The light-emitting device of claim 2, wherein each VCSEL in the first array of VCSELs includes a high-resistivity current-confinement region that resistively isolates a laser cavity of the VCSEL from a laser cavity of an adjacent VCSEL in the first array of VCSELs.

7. The light-emitting device of claim 1, further comprising a buffer layer disposed between the first set of material layers and the second set of material layers.

8. The light-emitting device of claim 7, wherein the buffer layer is disposed between an upper mirror included in the first set of material layers and a lower mirror included in the second set of material layers.

9. The light-emitting device of claim 1, wherein the first set of material layers comprises a first set of epitaxially grown layers and the second set of material layers comprises a second set of epitaxially grown layers.

10. The light-emitting device of claim 1, wherein the first VCSEL comprises a multi-junction VCSEL and the second VCSEL comprises a single-junction VCSEL.

11. A method of forming a light-emitting device, the method comprising:
forming a first set of material layers on a semiconductor substrate and a second set of material layers on the first set of material layers;
etching a portion of the second set of material layers to expose a top mirror layer included in the first set of material layers;
performing ion implantation on the first set of material layers and the second set of material layers to form a first isolated laser cavity within the first set of material layers and a second isolated laser cavity within the second set of material layers;
separating a die portion from the semiconductor substrate, wherein the die portion includes the first isolated laser cavity and the second isolated laser cavity.

12. The method of claim 11, further comprising simultaneously forming a first aperture associated with the first isolated laser cavity and a second aperture associated with the second isolated laser cavity via a single oxidation process.

13. The method of claim 12, further comprising, prior to the single oxidation process, forming at least one oxidation trench for forming the first aperture and at least one oxidation trench for forming the second aperture.

14. The method of claim 13, wherein forming the at least one oxidation trench for forming the first aperture and the at least one oxidation trench for forming the second aperture comprises performing a single etch process on the first set of material layers and the second set of material layers simultaneously.

15. The method of claim 11, further comprising, forming a first electrical connection to a top region of the first set of material layers and a second electrical connection to a top region of the second set of material layers.

16. The method of claim 15, wherein the top region of the first set of material layers comprises the top mirror layer and the top region of the second set of material layers comprises a top mirror layer included in the second set of material layers.

17. The method of claim 15, wherein forming the first electrical connection and the second electrical connection comprises simultaneously depositing a metal layer on the top region of the first set of material layers and a metal layer on the top region of the second set of material layers in a single metal deposition process.

18. The method of claim 11, wherein forming the first set of material layers on the semiconductor substrate comprises epitaxially growing the first set of material layers on the semiconductor substrate.

19. The method of claim 11, wherein the first set of material layers includes an undoped buffer layer on which the second set of material layers is formed.

20. The method of claim 11, wherein performing the ion implantation on the first set of material layers and the second set of material layers comprises performing a single ion implantation process simultaneously on the first set of material layers and the second set of material layers.
